(19) United States
(12) Patent Application Publication
(10) Pub. No.: US 2011/0006704 A1
(43) Pub. Date: Jan. 13, 2011

(54) LEAD FRAME BY WIRE BINDING METHOD AND LED POWER LAMP USING SAME

(75) Inventor: Nam-Gyu Kim, Seoul (KR)

Correspondence Address: AMPACC Law Group, PLLC, 6100 219th Street SW, Suite 580, Mountlake Terrace, WA, 98043, US

(73) Assignee: Corelux Co., Ltd., Seongnam (KR)

(21) Appl. No.: 12/922,160

(22) PCT Filed: Feb. 5, 2009
(86) PCT No.: PCT/KR09/00553

§ 371 Date: Sep. 13, 2010

(30) Foreign Application Priority Data
Mar. 12, 2008 (KR) 10-2008-0022990

(51) Int. Cl. H05B 37/02; H01L 23/495

(52) U.S. Cl. 315/294; 257/666; 257/E23.031

(57) ABSTRACT

The present invention provides an approach for overcoming the problem of using a printed circuit board for mounting LEDs in a conventional LED lamp. Provided is a lead frame by a wire binding method including: a main body (10) mounted with a semiconductor chip; an input unit (20) extending from one side of the main body (10) and having one end with a wire hole (21) with a predetermined diameter for the passage of a wire; and an output unit (30) extending from the other side of the main body (10) and having one end with a wire hole (21) with a predetermined diameter for the passage of a wire. The invention further relates to an LED power lamp using same.

### FIELD OF THE INVENTION

The present invention relates to a lead frame using a wire binding method and a light emitting diode (LED) power lamp including the same, and more particularly, to a lead frame using a wire binding method and an LED power lamp, in which a plurality of lead frame terminals are formed to have different lengths so as not to be mutually shorted, and therefore, a plurality of lead frames are bonded using only wires, whereby an LED lamp can be manufactured without using a printed circuit board for mounting LEDs.

### BACKGROUND OF THE INVENTION

Generally, a printed circuit board refers to a thin plate on which various electric components, such as integrated circuits, resistors and switches, are soldered.

Most circuits using electric or electronic devices are mounted on printed circuit boards. As for a typical method for manufacturing a printed circuit board, a copper foil is coated on a thin board made of an insulator such as an epoxy resin or a Bakelite resin, and a resist is printed onto circuit wires intended to remain as the copper foil. Then, the printed board is dipped into an etching solution which can dissolve copper. As a result, a portion where the resist is not printed is dissolved. When the resist is removed, the copper foil remains in a desired shape. Holes are drilled at positions where components are to be inserted, and a blue lead resist is printed onto positions where lead needs not be coated.

However, in most cases of configuring circuits using such printed circuit boards, soldering is used for connecting and fixing electric or electronic components on the boards. Hence, when manufacturing or discarding such boards, persons and environments are harmfully affected. Since printed circuit boards are usually made of epoxy or Bakelite resin which is lack of ductility and has many limitations on bending, they are vulnerable to damage by an external force greater than a specific limit. Furthermore, even flexible boards which are getting the spotlight with the recent display technology development have trouble solving the above problems.

### SUMMARY OF THE INVENTION

It is, therefore, an object of the present invention to provide a lead frame using a wire binding method, which requires no soldering and therefore contributes to the protection of environment.

Another object of the present invention is to provide an LED power lamp, which requires no printed circuit board for mounting LEDs.

Still another object of the present invention is to provide an LED power lamp, in which a plurality of lead frames are mutually connected through wires in a simple manner and thus manufacturing thereof can be easily achieved.

In accordance with an aspect of the present invention, there is provided a lead frame using a wire binding method, which includes: a main body mounted with a semiconductor chip; an input port extending from one side of the main body and having one end portion with a wire hole with a predetermined diameter, such that a wire passes through the wire hole in a connected state; and an output port extending from the other side of the main body and having one end portion with a wire hole with a predetermined diameter, such that a wire passes through the wire hole in a connected state.

In the present invention, the wire holes are formed by winding the input port and the output port, which extend from the main body, at least one turn.

In the present invention, the input port and the output port are covered with an insulating material, except for the end portions where the wire the wire holes are formed.

In accordance with another aspect of the present invention, there is provided a lead frame using a wire binding method, which includes: a main body mounted with a semiconductor chip; a common terminal extending from one side of the main body and having an end portion with a wire hole with a predetermined diameter, such that a wire passes through the wire hole in a connected state; and a plurality of power terminals extending from the other side of the main body and having end portions with wire holes with a predetermined diameter, such that wires pass through the wire holes in a connected state, wherein the plurality of power terminals are formed to have different lengths.

In the present invention, the wire holes are formed by winding the common terminal and the plurality of power terminals, which extend from the main body, at least one turn.

In the present invention, the common terminal and the plurality of power terminals are covered with an insulating material, except for the end portions where the wire holes are formed.

In the present invention, the wires passing through the wire holes of the power terminals are not directly connected together.

In accordance with further another aspect of the present invention, there is provided an LED power lamp, which includes: a power supply unit for supplying a voltage; a voltage division unit for dividing the voltage supplied from the power supply unit by dropping the supplied voltage to a predetermined voltage; a first wire electrically connected to the voltage division unit; a plurality of lead frames for receiving a voltage from the first wire; a second wire having one side connected to the voltage division unit and grounded, and connected to output ports of the lead frames; and a plurality of LEDs mounted on main bodies of the lead frames to emit light.

In the present invention, both sides of the first wire and the second wire are fixed by fastening members.

In accordance with still further aspect of the present invention, there is provided an LED power lamp, which includes: a power supply unit for receiving a voltage; a voltage division unit for dividing the voltage supplied from the power supply unit by dropping the supplied voltage to a predetermined voltage; a first wire electrically connected to the voltage division unit; a plurality of lead frames for receiving a common voltage from the first wire; a plurality of second wires having one side connected to the voltage division unit and grounded, and connected to a plurality of power terminals of the lead frames, respectively; and a plurality of LEDs mounted on main bodies of the lead frames to emit light.

In the present invention, both sides of the first wire and the plurality of second wires are fixed by fastening members.

As described above, in the lead frame employing the wire binding method and the LED power lamp using the same in accordance with the present invention, the terminals connected to the main body of the lead frame are connected using only the wires, and thus soldering is not required to configure a separate circuit for the connection, thereby contributing to the protection of environment.

Also, the LED power lamp in accordance with the present invention requires no printed circuit board because the LED is mounted on the lead frame and the lead frame is connected using the wires.

Additionally, the LED power lamp in accordance with the present invention can be easily manufactured because the plurality of lead frames on which the LEDs are mounted can be easily connected together through the wires.

### BRIEF DESCRIPTION OF THE DRAWINGS

FIGS. 1 to 4 show a lead frame using a wire binding method in accordance with a first embodiment of the present invention;

FIGS. 5 to 8 show a lead frame using a wire binding method in accordance with a second embodiment of the present invention; and

FIGS. 9 and 10 show LED power lamps employing the lead frames using the wire binding method in accordance with the first and second embodiments of the present invention.

### DETAILED DESCRIPTION OF THE EMBODIMENTS

Hereinafter, a lead frame using a wire binding method and an LED power lamp employing the same in accordance with the present invention.

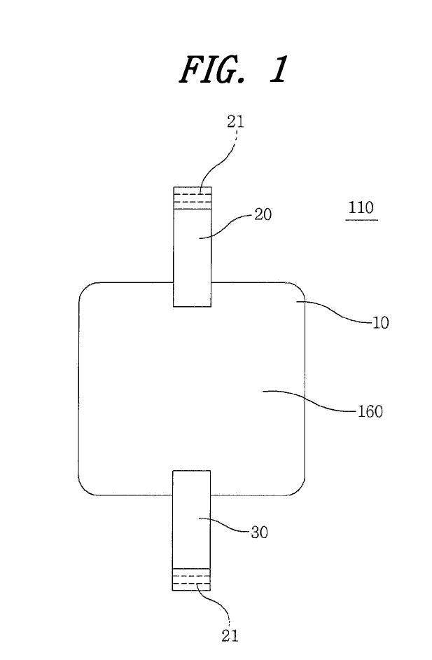

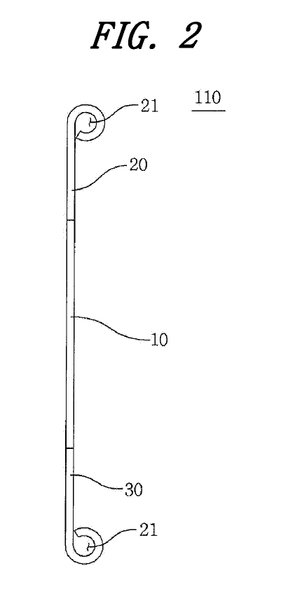

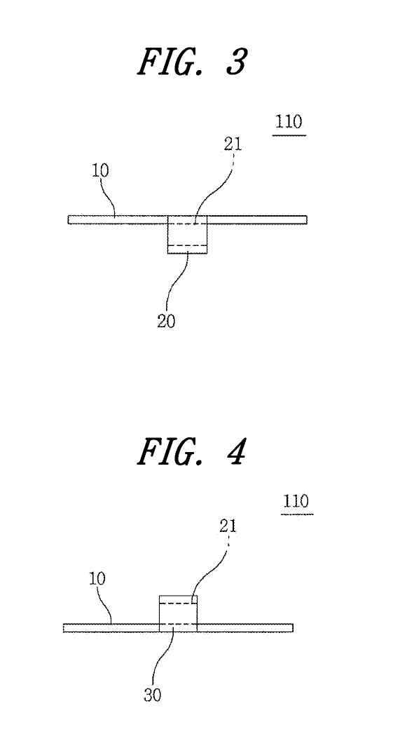

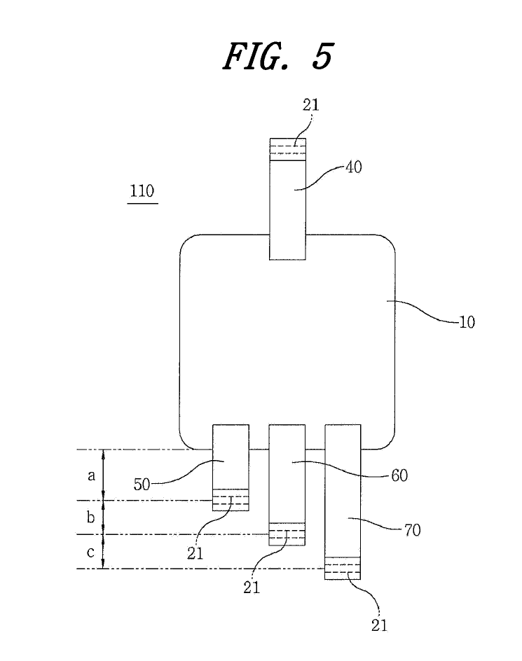

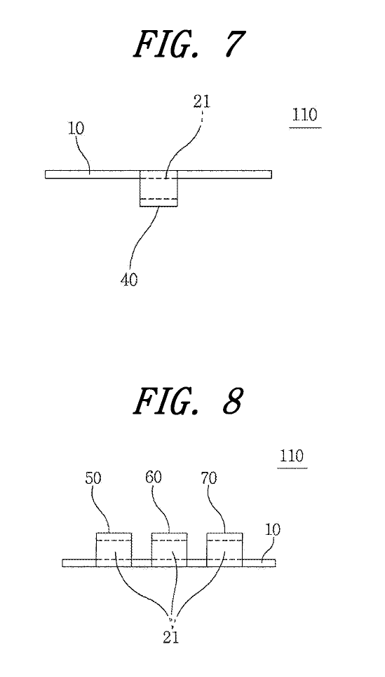

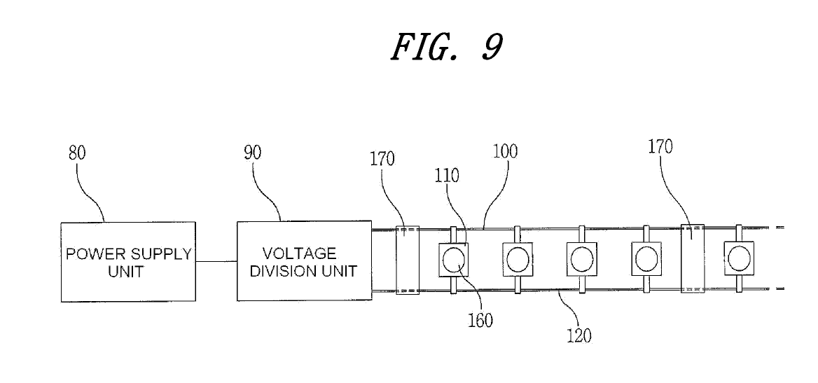

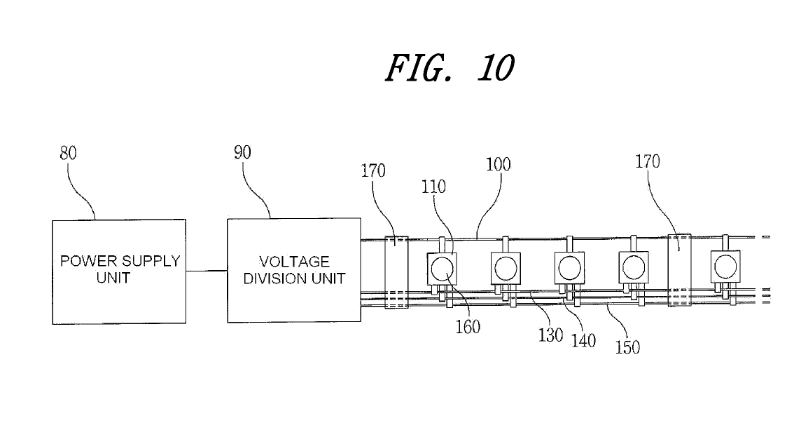

FIGS. 1 to 4 show a lead frame using a wire binding method in accordance with a first embodiment of the present invention; FIGS. 5 to 8 show a lead frame using a wire binding method in accordance with a second embodiment of the present invention; and FIGS. 9 and 10 show LED power lamps including the lead frames using the wire binding method in accordance with the first and second embodiments of the present invention.

Referring to FIGS. 1 to 4, a lead frame in accordance with a first embodiment of the present invention includes a main body 10 mounted with a semiconductor chip, an input port 20 extending from one side of the main body 10, and an output port 30 extending from the other side of the main body 10.

The main body 10 is of an insulator for mounting the semiconductor chip, for example, an LED 160. The input port 20 extends from the one side of the main body 10 to form a contact point with which the semiconductor chip is contacted. The output port 30 extends from the other side of the main body 10.

The input port 20 is of a conductive metal material which extends from one side of the main body 10 and is partially included in the main body 10 to form a contact point with the semiconductor chip. A wire hole 21 with a predetermined diameter of, for example, 0.3 mm, is formed at an end center portion of the input port 20, such that a wire passes through the wire hole 21 in a connected state. The wire hole 21 may be formed by sufficiently elongating the input port 20 and winding an end portion of the elongated input port 20 at least one turn.

The output port 30 is provided in the same manner as that of the input port 20. The output port 30 is provided at the other side of the main body 10 and connected to another wire different from the wire connected to the input port 20.

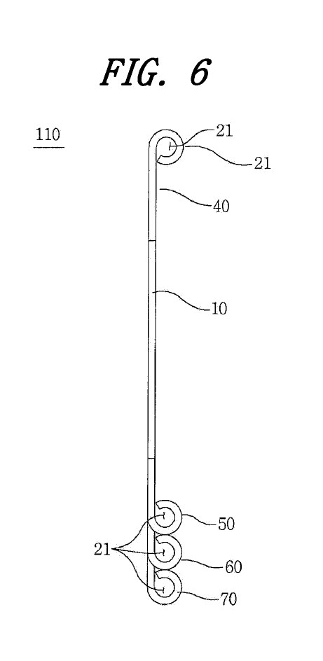

Referring to FIGS. 5 and 6, a lead frame in accordance with a second embodiment of the present invention includes a main body 10 mounted with a semiconductor chip, a common terminal 40 extending from one side of the main body 10, a first power terminal 50 extending from the other side of the main body 10, a second power terminal 60 arranged in parallel to the first power terminal 50 and having a length greater than that of the first power terminal 50, and a third power terminal 70 arranged in parallel to the second power terminal 60 and having a length greater than that of the second power terminal 60.

As described above, the main body 10 is an insulator for mounting the semiconductor chip, for example, an LED 160. The common terminal 40 extends from the one side of the main body 10 and connects to the semiconductor chip. In the same manner as that of the common terminal 40, the first, second and third power terminals 50, 60 and 70 extend from the other side of the main body 10.

The common terminal 40 is of a conductive metal material which extends from one side of the main body 10 and is partially included in the main body 10 to form a contact point with the semiconductor chip. A wire hole 21 for the passage of a wire with a predetermined diameter of, for example, 0.3 mm, is formed at an end center portion of the common terminal 40, such that a wire passes through the wire hole 21 in a connected state. In the same manner as that of the common terminal 40, the wire hole 21 may be formed by sufficiently elongating the common terminal 40 and winding an end portion of the elongated common terminal 40 at least one turn.

The first, second and third power terminals 50, 60 and 70 have the same shape as that of the common terminal 40. However, as shown in FIG. 5, the first, second and third power terminals 50, 60 and 70 extend from the other side of the main body 10. The second power terminal 60 is longer than the first power terminal 50 by a predetermined length b, and the third power terminal 70 is longer than the second power terminal 60 by a predetermined length c, thereby having length differences a, b and c. The wires passing through and connecting to the wire holes 21 formed in the first, second and third power terminals 50, 60 and 70 are not directly connected to one another, thereby preventing electrical shorting caused by the mutual connection of the wires.

Furthermore, the input port 20, the output port 30 and the first, second and third power terminals 50, 60 and 70 are covered with an insulating material, except for their end portions where the wire holes 21 are formed, thereby preventing electrical shorting between the wires passing through and connecting to the wire holes 21.

Meanwhile, electrical shorting between the wires can be prevented by the length differences, and electrical shorting may also be prevented by forming the first, second and third power terminals 50, 60 and 70 with height differences.

In order for secure connection between the wires and the terminals, the end portions where the wire holes 21 are formed are compressed such that the wires passing through and connecting to the input port 10, the output port 20, and the first, second and third power terminals 50, 60 and 70 can be fixedly connected to the terminals.

Referring to FIG. 9, an LED power lamp employs the lead frame using the wire binding method in accordance with the first embodiment of the present invention. The LED power lamp includes a power supply unit 80 for supplying a voltage, a voltage division unit 90 for dividing the voltage supplied from the power supply unit 80 by dropping the supplied voltage to a predetermined voltage, a first wire 100 connected to the voltage division unit 90, a plurality of lead frames 110 of the first embodiment for receiving a voltage through the first wire 100, a second wire 120 connected to the ground of the voltage division unit 90 and connected to output ports 30 of the lead frames 110, and a plurality of LEDs 160 mounted on main bodies 10 of the lead frames 110.

The power supply unit 80 is a type of a plug which transfers an office, domestic or commercial voltage, for example, 220 V, to lamps. The power supply unit 80 may be configured in various shapes according to the size and type of a power lamp.

The voltage division unit 90 is a circuit which drops the voltage supplied from the power supply unit 80 to a predetermined voltage and applies the dropped voltage through the first wire 100 to the input ports 20 of the lead frames 110 in order for light emission of the LEDs 160. That is, the voltage division unit 90 supplies a driving voltage necessary for the light emission of the LEDs 160 mounted on the lead frames 110.

The first wire 100 has one end portion connected to the voltage division unit 90 so that the voltage regulated by the voltage division unit 90 is provided to the input ports 20 of the lead frames 110. The first wire 100 passes through the wire holes 21 of the input ports 20 of the lead frames 110 in a connected state. The first to fifth wires 100, 120 130, 140 and 150 are made of a conductive metal material (for example, a copper wire), which is not covered with an insulator.

The second wire 120 has one end portion connected to the ground of the voltage division unit 90 and passes through the wire holes 21 of the output ports 30 of the lead frames 110 in a fixedly connected state.

The LEDs 160 are mounted on the main bodies 10 of the lead frames 110. The LEDs 160 are supplied with the appropriate driving voltage from the voltage division unit 90 and emit light. Various types of typical LEDs may be selectively used as the LEDs 160.

Referring to FIG. 10, an LED power lamp employs the lead frame using the wire binding method in accordance with the second embodiment of the present invention. The LED power lamp includes a power supply unit 80 for supplying a voltage, a voltage division unit 90 for dividing the voltage supplied from the power supply unit 80 by dropping the supplied voltage to a plurality of predetermined voltage levels, a first wire 100 connected to the voltage division unit 90, a plurality of lead frames 110 of the second embodiment for receiving a common voltage through the first wire 100, a plurality of second wires 130, 140 and 150 having one side connected to the ground of the voltage division unit 90 and connected to first, second and third power terminals 50, 60 and 70, and a plurality of LEDs 160 mounted on main bodies 10 of the lead frames 110.

The power supply unit 80, the first wire 100, and the LEDs 160 are substantially identical to those of the LED power lamp in accordance with the first embodiment of the present invention, and therefore detailed description thereof will be omitted.

The voltage division unit 90 is a circuit which divides the supplied voltage by dropping the supplied voltage to a voltage to be supplied to the common terminal 40 and voltages to be supplied to the first, second and third power terminals 50, 60 and 70. The LEDs 160 mounted on the lead frames 110 may be controlled by regulating the voltages to be applied to the first, second and third power terminals 50, 60 and 70 through the voltage division unit 90. For example, in the case in which the first, second and third power terminals 50, 60 and 70 are terminals for light emission of red, green and blue areas of the LEDs 160 mounted on the lead frames 110, respectively, for example, +3 V is applied to the common terminal 40, 0 V is applied to the first power terminal 50, and +3 V is applied to the second and third power terminals 60 and 70. As a result, the red area corresponding to the first power terminal 50 is activated and the LED lamp in the red area emits red light. In this manner, the LEDs 160 may provide a variety of color illumination by individually or simultaneously controlling the three terminals 50, 60 and 70 through the voltage division unit 90.

The second wires 130, 140 and 150 are connected to the ground of the voltage division unit 90 and connected to the first, second and third power terminals 50, 60 and 70 of the lead frames 110, respectively, so that the predetermined voltages controlled by the voltage division unit 90 are applied to the LEDs 160.

In the LED power lamps employing the lead frames in accordance with the first and second embodiments of the present invention, both sides of the wires 100, 120, 130, 140 and 150 used therein are fixed by fastening members 170, for example, plastic brackets, thereby preventing the wires from being directly connected together due to their extension.

In the LED power lamps including the lead frames in accordance with the first and second embodiments of the present invention, the plurality of LEDs are electrically connected through the wires and thus they can be bent or transformed in various shapes. Hence, bar-shaped LED lamps may be easily manufactured. By making an outer case of a plastic material having excellent ductility, the components of the LED lamp within the case may be protected. Also, lamps can be manufactured in various shapes suitable for their purposes, for example, an image shape or a text shape.

1. A lead frame using a wire binding method, comprising:
a main body mounted with a semiconductor chip;
an input port extending from one side of the main body and having one end portion with a wire hole with a predetermined diameter, such that a wire passes through the wire hole in a connected state; and
an output port extending from the other side of the main body and having one end portion with a wire hole with a predetermined diameter, such that a wire passes through the wire hole in a connected state.

2. The lead frame of claim 1, wherein the wire holes are formed by winding the input port and the output port, which extend from the main body, at least one turn.

3. The lead frame of claim 1, wherein the input port and the output port are covered with an insulating material, except for the end portions where the wire the wire holes are formed.

4. A lead frame using a wire binding method, comprising:
a main body mounted with a semiconductor chip;
a common terminal extending from one side of the main body and having an end portion with a wire hole with a predetermined diameter, such that a wire passes through the wire hole in a connected state; and
a plurality of power terminals extending from the other side of the main body and having end portions with wire holes with a predetermined diameter, such that wires pass through the wire holes in a connected state,
wherein the plurality of power terminals are formed to have different lengths.

5. The lead frame of claim 4, wherein the wire holes are formed by winding the common terminal and the plurality of power terminals which extend from the main body, at least one turn.

6. The lead frame of claim 4, wherein the common terminal and the plurality of power terminals are covered with an insulating material, except for the end portions where the wire holes are formed.

7. The lead frame of claim 4, wherein the wires passing through the wire holes of the power terminals are not directly connected together.

8. An LED power lamp comprising:
a power supply unit for supplying a voltage;
a voltage division unit for dividing the voltage supplied from the power supply unit by dropping the supplied voltage to a predetermined voltage;
a first wire electrically connected to the voltage division unit;
a plurality of lead frames for receiving a voltage from the first wire;
a second wire having one side connected to the voltage division unit and grounded, and connected to the lead frames; and
a plurality of LEDs mounted on the lead frames to emit light.

9. The LED power lamp of claim 8, wherein both sides of the first wire and the second wire are fixed by fastening members.

10. An LED power lamp comprising:
a power supply unit for receiving a voltage;
a voltage division unit for dividing the voltage supplied from the power supply unit by dropping the supplied voltage to a predetermined voltage;
a first wire electrically connected to the voltage division unit;
a plurality of lead frames for receiving a common voltage from the first wire;
a plurality of second wires having one side connected to the voltage division unit and grounded, and connected to the lead frames, respectively; and
a plurality of LEDs mounted on the lead frames to emit light.

11. The LED power lamp of claim 10, wherein both sides of the first wire and the plurality of second wires are fixed by fastening members.

12. The LED power lamp of claim 8, wherein each of the lead frames includes:
a main body mounted with a semiconductor chip;
an input port extending from one side of the main body and having one end portion with a wire hole with a predetermined diameter, such that a wire passes through the wire hole in a connected state; and
an output port extending from the other side of the main body and having one end portion with a wire hole with a predetermined diameter, such that a wire passes through the wire hole in a connected state.

13. The LED power lamp of claim 10, wherein each of the lead frames includes:
a main body mounted with a semiconductor chip;
a common terminal extending from one side of the main body and having an end portion with a wire hole with a predetermined diameter, such that a wire passes through the wire hole in a connected state; and
a plurality of power terminals extending from the other side of the main body and having end portions with wire holes with a predetermined diameter, such that wires pass through the wire holes in a connected state,
wherein the plurality of power terminals are formed to have different lengths.
